(19) United States
(12) Patent Application Publication
(10) Pub. No.: US 2023/0176489 A1
(43) Pub. Date: Jun. 8, 2023

(54) DETECTING APPARATUS, SUBSTRATE PROCESSING APPARATUS, AND ARTICLE MANUFACTURING METHOD

(71) Applicant: CANON KABUSHIKI KAISHA, Tokyo (JP)

(72) Inventor: Yuki ISAKA, Tochigi (JP)

(21) Appl. No.: 17/994,436

(22) Filed: Nov. 28, 2022

(30) Foreign Application Priority Data
Dec. 6, 2021 (JP) 2021-197756

(51) Int. Cl. G03F 7/20; G03F 9/00; G06T 7/00

(52) U.S. Cl. CPC G03F 7/70625; G03F 7/70633; G03F 9/7088; G06T 7/0004; G06T 2207/30148

(57) ABSTRACT

A detecting apparatus configured to detect a position of a predetermined pattern on a substrate includes a first detecting system configured to detect a position of a first predetermined pattern in a first field of view, and a second detecting system configured to detect a position of a second predetermined pattern with a smaller shift amount than that of the first predetermined pattern in a second field of view narrower than the first field of view.

### BACKGROUND

### Technical Field

One of the aspects of the disclosure relates to a detecting apparatus, a substrate processing apparatus, and an article manufacturing method.

### Description of the Related Art

There has conventionally been known a method of detecting a position of an alignment mark on a substrate in an exposure apparatus by performing rough detection using a mark detecting system with a wide field of view (low-magnification detecting system) and then fine detection using a mark detecting system with a narrow field of view (high-magnification detecting system).

Japanese Patent Laid-Open No. (“JP”) 2005-116779 discloses a configuration for detecting a plurality of alignment marks on a substrate at high speed using a plurality of detecting systems that can switch between a low-magnification detecting system and a high-magnification detecting system.

JP 10-223528 discloses a configuration for simultaneously detecting a plurality of alignment marks on a substrate using a single detecting system.

However, the configuration disclosed in JP 2005-116779 requires a plurality of detecting systems that can switch between the low-magnification detecting system and the high-magnification detecting system, and causes the configuration to be complicated and the space for the configuration to be larger.

The configuration disclosed in JP 10-223528 needs to accommodate the plurality of alignment marks within the field of view, and causes both the field of view and the detecting system to be larger.

### SUMMARY

One aspect of the disclosure provides a detecting apparatus that can detect positions of a plurality of marks on a substrate with high speed and high accuracy with a simple configuration.

A detecting apparatus according to one aspect of the disclosure is configured to detect a position of a predetermined pattern on a substrate and includes a first detecting system configured to detect a position of a first predetermined pattern in a first field of view, and a second detecting system configured to detect a position of a second predetermined pattern with a smaller shift amount than that of the first predetermined pattern in a second field of view narrower than the first field of view.

A substrate processing apparatus according to another aspect of this disclosure is configured to process a substrate and includes the above detecting apparatus. An article manufacturing method according to another aspect of this disclosure includes the steps of processing a substrate using the above substrate processing apparatus, and manufacturing an article from a processed substrate.

Further features of the disclosure will become apparent from the following description of exemplary embodiments with reference to the attached drawings.

### BRIEF DESCRIPTION OF THE DRAWINGS

FIG. 1 is a schematic view of an exposure apparatus having a mark detecting apparatus according to a first embodiment.

FIGS. 2A and 2B are configuration diagrams of the mark detecting apparatus according to the first embodiment.

FIGS. 3A to 3C explain a rough detection method using the mark detecting apparatus according to the first embodiment.

FIGS. 4A to 4F explain a searching method using the mark detecting apparatus according to the first embodiment.

FIGS. 5A and 5B are configuration diagrams of a mark detecting apparatus according to a second embodiment.

FIGS. 6A and 6B are configuration diagrams of a mark detecting apparatus according to a comparative example.

FIGS. 7A to 7F explain a method of performing rough detection and fine detection using the mark detecting apparatus according to the comparative example.

### DESCRIPTION OF THE EMBODIMENTS

Referring now to the accompanying drawings, a detailed description will be given of embodiments according to the disclosure. Corresponding elements in respective figures will be designated by the same reference numerals, and a duplicate description thereof will be omitted.

### First Embodiment

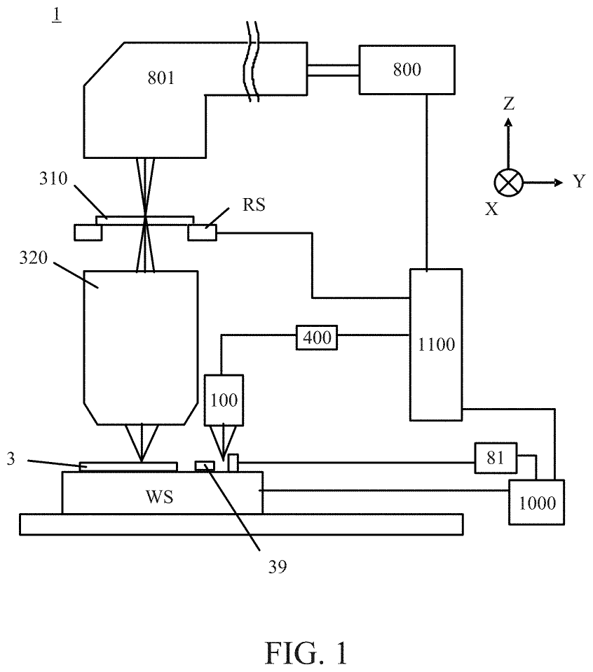

FIG. 1 is a schematic view of an exposure apparatus 1 having a mark detecting apparatus (detecting apparatus) 100 according to this embodiment. This embodiment will describe an exposure apparatus that exposes a substrate to form a pattern on the substrate as an example of a substrate processing apparatus. The exposure apparatus 1 includes a light source unit 800, an illumination optical system 801, a reticle stage RS on which a reticle 310 is to be mounted, a projection optical system 320, a wafer stage WS on which a wafer (substrate) 3 is to be mounted, a mark detecting apparatus 100, and a calculation processing unit 400. A reference plate 39 is disposed on the wafer stage WS. A control unit 1100 includes a CPU and memory, is electrically connected to the light source unit 800, the reticle stage RS, the wafer stage WS, and the mark detecting apparatus 100, and controls the operation of the exposure apparatus 1. The control unit 1100 also performs correction calculation and control of detection values in a case where the mark detecting apparatus 100 detects a surface position of the wafer 3. Although the exposure apparatus 1 is a scan-type exposure apparatus (scanner) in this embodiment, it may be a step-and-repeat exposure apparatus (stepper).

The light source unit 800 includes, for example, a laser such as an ArF excimer laser with a wavelength of approximately 193 nm or a KrF excimer laser with a wavelength of approximately 248 nm. The type of light source is not limited to excimer lasers. More specifically, the light source unit 800 includes an F₂ laser with a wavelength of approximately 157 nm, EUV (Extreme Ultraviolet) light with a wavelength of 20 nm or less, and a mercury lamp with such a wavelength as 365 nm (i-line), 405 nm (h-line), or 436 nm (g-line).

The illumination optical system 801 includes a lens, a mirror, an optical integrator, an aperture stop (diaphragm), and the like, shapes a light beam (luminous flux) emitted from the light source unit 800 into an exposure slit having a predetermined shape optimal to exposure, and illuminates the reticle 310.

The reticle 310 is made, for example, of quartz and has a circuit pattern to be transferred. Diffracted light from the reticle 310 passes through the projection optical system 320 and is projected onto the wafer 3. The reticle 310 and the wafer 3 are arranged in an optically conjugate relationship. The pattern of the reticle 310 is transferred onto the wafer 3 by scanning the reticle 310 and the wafer 3 at a speed ratio of a reduction ratio. The exposure apparatus 1 is provided with an unillustrated reticle detecting unit, and the reticle 310 is disposed at a predetermined position by the reticle detecting unit.

The reticle stage RS supports the reticle 310 via unillustrated reticle chucks and is connected to an unillustrated moving mechanism. The moving mechanism includes a linear motor or the like, and can move the reticle 310 by driving the reticle stage RS in an X-axis direction, a Y-axis direction, a Z-axis direction, and rotation directions around each axis.

The projection optical system 320 has the function of imaging a light beam from an object plane onto an image plane, and images diffracted light that has passed through the circuit pattern formed on the reticle 310 onto the wafer 3. The projection optical system 320 includes a dioptric optical system including a plurality of lens elements, a catadioptric optical system including a plurality of lens elements and at least one concave mirror, an optical system including a plurality of lens elements and a diffractive optical element such as at least one kinoform lens, or the like.

The wafer 3 is an object to be processed, and is coated with a photoresist. The mark detecting apparatus 100 detects positions of marks 132 on the wafer 3. An unillustrated surface position detecting apparatus detects the surface position of the wafer 3. Instead of the wafer 3, a liquid crystal substrate or another object to be processed may be placed on the wafer stage WS. The mark detecting apparatus 100 detects the position of the mark 132 in this embodiment, but instead of the mark, it may detect a position of a predetermined pattern including a predetermined characteristic such as a via or part of a circuit pattern.

The wafer stage WS supports the wafer 3 via an unillustrated wafer chuck and is connected to an unillustrated moving mechanism. The moving mechanism includes a linear motor or the like, and can move the wafer 3 in the X-axis direction, the Y-axis direction, the Z-axis direction, and a rotation direction of each axis. The positions of the reticle stage RS and the wafer stage WS are monitored, for example, by a six-axis laser interferometer 81 or the like, and a stage position controller 1000 drives the reticle stage RS and wafer stage WS at a constant speed ratio.

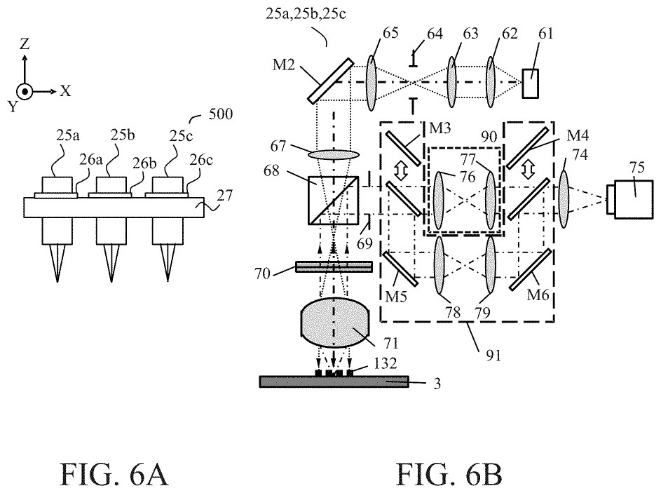

FIG. 6A is a configuration diagram of a mark detecting apparatus 500 according to a comparative example. The mark detecting apparatus 500 includes mark detecting systems 25a to 25c and driving mechanisms 26a to 26c. The mark detecting systems 25a to 25c include detection areas and are disposed at different positions along the X-axis direction. The driving mechanisms 26a to 26c hold the mark detecting systems 25a to 25c and can be driven relative to a detecting system frame 27 in the X-axis direction with a predetermined stroke. By driving the driving mechanisms 26a to 26c, the positions of the detection areas of the mark detecting systems 25a to 25c in the X-axis direction can be adjusted. The driving directions of the driving mechanisms 26a to 26c are not limited to the X-axis direction, and may be the Y-axis direction or the Z-axis direction. Alternatively, the position of the detection area of the mark detecting system 25b may be fixed without providing the driving mechanism 26b, and the positions of the detection areas of the mark detecting systems 25a and 25c may be adjusted using the driving mechanisms 26a and 26c.

FIG. 6B illustrates an example of the configurations of the mark detecting systems 25a to 25c. Each of the mark detecting systems 25a to 25c includes a low-magnification detecting system with a wide field of view and a high-magnification detecting system with a narrow field of view, and the low-magnification detecting system and the high-magnification detecting system are switchable by switching mirrors M3 and M4. Each of the mark detecting systems 25a to 25c includes an illumination system that illuminates the wafer 3 with light emitted from a light source 61 and an imaging system that images the marks 132 on the wafer 3.

The illumination system includes illumination optical systems 62, 63, and 65, an illumination aperture stop 64, a mirror M2, a relay lens 67, a polarizing beam splitter (PBS) 68, a quarter waveplate 70, and an objective optical system 71. The imaging system includes the objective optical system 71, the quarter waveplate 70, a detection aperture stop 69, the PBS 68, a high-magnification relay system 90, a low-magnification relay system 91, and an imaging optical system 74. The high-magnification relay system 90 includes high-magnification relay optical systems 76 and 77. The low-magnification relay system 91 includes the switching mirrors M3 and M4, mirrors M5 and M6, and low-magnification relay optical systems 78 and 79. In detection at high magnification, the high-magnification relay system 90 is used, in detection at low magnification, the low-magnification relay system is used, and reflected light from each mark 132 is imaged on a sensor 75. A coordinate position of each mark 132 is calculated based on positional information on the wafer stage and a signal regarding the mark 132.

Light emitted from the light source 61 passes through illumination optical systems 62 and 63 and reaches the illumination aperture stop 64 disposed at a pupil position of the wafer 3. A light beam diameter at the illumination aperture stop 64 is sufficiently smaller than that of the light source 61. The light passing through the illumination aperture stop 64 passes through the illumination optical system 65, the mirror M2, and the relay lens 67 and is guided to the PBS 68. The PBS 68 transmits P-polarized light parallel to the Y-axis direction and reflects S-polarized light parallel to the X-axis direction. Hence, the P-polarized light that has transmitted through the PBS 68 transmits through the quarter waveplate 70 and is converted into circularly polarized light, passes through the objective optical system 71, and Koehler-illuminates the marks 132 formed on the wafer 3.

The light reflected, diffracted, and scattered by the mark 132 passes through the objective optical system 71 again, passes through the quarter waveplate 70, is converted from circularly polarized light into S-polarized light, and is reflected by the PBS 68. The PBS 68 separates an optical path into an optical path of the illumination light to the wafer 3 and an optical path of the reflected light from the wafer 3. The polarization state of the light reflected by the mark 132 becomes circularly polarized in a rotating direction opposite to the circularly polarized light irradiated onto the mark 132. That is, in a case where the polarization state of the light irradiated to the mark 132 is right-handed circularly polarized light, the polarization state of the light reflected by the mark 132 is left-handed circularly polarized light.

The light reflected by the PBS 68 passes through the detection aperture stop 69. The detection aperture stop 69 switches the numerical aperture of the reflected light from the mark 132 by changing an F-number (aperture value) according to a command from a control unit (not illustrated). During high-magnification detection, the switching mirrors M3 and M4 are retracted from the optical path, and the light passing through the detection aperture stop 69 is guided to the sensor 75 via the high-magnification relay system 90 and the imaging optical system 74. During low-magnification detection, the switching mirrors M3 and M4 are inserted into the optical path, and the light passing through the detection aperture stop 69 is guided to the sensor 75 via the low-magnification relay system 91 and the imaging optical system 74. Therefore, the high-magnification detecting system and the low-magnification detecting system can be switched by inserting and ejecting the switching mirrors M3 and M4, and an image of the mark 132 on the wafer 3 is formed on the sensor 75. A beam splitter or the like may be used instead of the switching mirrors M3 and M4. Alternatively, the high-magnification detecting system and the low-magnification detecting system may form images on different sensors.

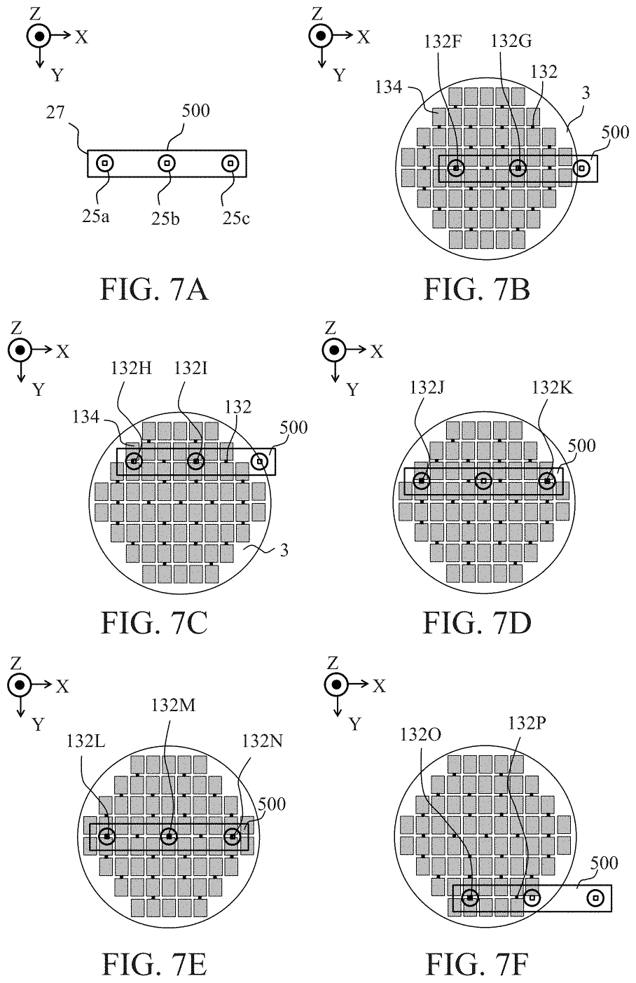

Referring now to FIGS. 7A to 7F, a description will be given of a method of performing rough detection for more accurately finding the position of (narrowing an existing range of) each mark 132 on the wafer 3 and fine detection following the rough detection using the mark detecting apparatus 500 according to the comparative example.

FIGS. 7A to 7F explain a method of performing the rough detection and the fine detection using the mark detecting apparatus 500 according to the comparative example. FIG. 7A illustrates the mark detecting apparatus 500 viewed from the Z-axis direction. FIG. 7B illustrates a positional relationship between the mark detecting apparatus 500 and the marks 132 in a case where the rough detection is performed by the low-magnification detecting system.

The mark detecting apparatus 500 performs rough detection of marks 132 partially formed of the entire shot area using the mark detecting systems 25a to 25c each switched to the low-magnification detecting system, as illustrated in FIG. 7B, in consideration of productivity. At that time, by controlling the wafer stage WS, the marks 132 are aligned with the detection areas of the mark detecting systems 25a to 25c, and the positions of the marks 132 are detected. At this time, the control unit 1100 controls the wafer stage WS so as to detect the positions of the plurality of marks 132 to be detected in the shortest possible time. More specifically, two marks 132 are simultaneously aligned with the detection areas of at least two of the mark detecting systems 25a to 25c, and the positions of the two marks 132 are detected. For example, as illustrated in FIG. 7B, two marks 132F and 132G are simultaneously aligned with the mark detecting systems 25a and 25b, and the positions of the marks 132F and 132G are detected. Thereby, a moving amount of the wafer stage WS, that is, the driving time of the wafer stage WS and the detecting time of the mark detecting apparatus 500 can be significantly reduced in comparison with a case where a plurality of marks 132 are sequentially aligned with the detection area of a single mark detecting system and its position is detected.

The control unit 1100 calculates shift (movement) and rotation (rotation) of the wafer 3 based on the rough detection results of the marks 132 using the detection areas of the mark detecting systems 25a to 25c. The control unit 1100 can more accurately find the position of (narrow an existing range of) the mark 132 by controlling the wafer stage WS based on the calculation result.

The mark detecting apparatus 500 performs fine detection using the mark detecting systems 25a to 25c switched to the high-magnification detecting system. FIGS. 7C, 7D, and 7E illustrate a positional relationship between the mark detecting apparatus 500 and the marks 132 at different times in detecting the marks 132. The mark detecting apparatus 500 sets the marks 132 partially formed on the entire shot area to the detection targets in consideration of productivity. At that time, by controlling the wafer stage WS, the marks 132 are aligned with the detection areas of the mark detecting systems 25a to 25c, and the positions of the marks 132 are detected. At this time, the control unit 1100 controls the wafer stage WS so as to detect the positions of the plurality of marks 132 that are detection targets in the shortest possible time. More specifically, two marks 132 are aligned with the detection areas within depths of focus of at least two of the mark detecting systems 25a to 25c, and the positions of the two marks 132 are detected. For example, as illustrated in FIG. 7C, two marks 132H and 1321 are simultaneously aligned with the mark detecting systems 25a and 25b, and the positions of the marks 132H and 1321 are detected. As illustrated in FIG. 7D, the mark detecting systems that are used for detection may be changed according to the layout of the marks 132. In FIG. 7D, two marks 132J and 132K are simultaneously aligned with the mark detecting systems 25a and 25c, and the positions of the two marks 132J and 132K are detected. As illustrated in FIG. 7E, three marks 132L, 132M, and 132N may be simultaneously aligned with the detection areas of the mark detecting systems 25a to 25c within their depths of focus, and the positions of the three marks 132L, 132M, and 132N may be detected. As illustrated in FIG. 7F, the mark detecting systems 25a to 25c may be able to detect only one mark 132 at a time. In this case, a driving distance of the wafer stage WS can be reduced by driving the wafer stage WS after a mark 132O is detected by the mark detecting system 25a and by detecting a mark 132P using the mark detecting system 25b.

Thereby, a moving amount of the wafer stage WS, that is, the driving time of the wafer stage WS and the detecting time of the mark detecting apparatus 500 can be significantly reduced in comparison with a case where a plurality of marks 132 are sequentially aligned with the detection area of a single mark detecting system and its position is detected.

The control unit 1100 calculates shift, magnification, and rotation of the array of the shot areas 134 on the wafer 3 based on the detection results of the marks 132 relative to the detection areas of the mark detecting systems 25a to 25c. Thereafter, the control unit 1100 corrects each item and determines the regularity of the lattice array. The control unit 1100 obtains a correction coefficient from the reference baseline and the regularity of the determined lattice arrangement, and aligns exposure light with the wafer 3 based on the result. At this time, the control unit 1100 may correct high-order components of the lattice array and a shot shape if necessary.

However, all of the mark detecting systems 25a to 25c are configured to switch between the low-magnification detecting system and the high-magnification detecting system, and thus the mark detecting apparatus 500 according to the comparative example has a complicated configuration and the space for the configuration increases. If the low-magnification detecting system is omitted in order to simplify the configuration, it is highly likely that the marks 132 become undetectable because the marks 132 will not fall within a field of view of the high-magnification detecting system due to detection errors of the marks 132 caused by a driving error of the wafer 3. Searching for the marks 132 using the high-magnification detecting system having the field of view narrower than that of the low-magnification detecting system increases the searching time.

Accordingly, the mark detecting apparatus 100 according to this embodiment includes a detecting system (primary eye, first detecting system) that includes both a low-magnification detecting system and a high-magnification detecting system, and a detecting system (secondary eye, second detecting system) that includes only a high-magnification detecting system. The secondary eye may have at least a field of view (second field of view) narrower than a field of view (first field of view) of the primary eye. During pre-alignment, the marks 132 located at the periphery of the wafer 3 are detected by the low-magnification detecting system of the primary eye, and the marks 132 located at the center of the wafer 3 are detected by the secondary eye. A description will now be given of a method of performing rough detection for more accurately finding the positions of the marks 132 on the wafer 3 and of performing fine detection after the rough detection, using the mark detecting apparatus 100 according to this embodiment.

In this embodiment, the primary eye includes both the low-magnification detecting system and the high-magnification detecting system, but the disclosure is not limited to this embodiment. For example, the primary eye may include only a low-magnification detecting system, or may include a low-magnification detecting system and a detecting system having a field of view (third field of view) narrower than that of the low-magnification detecting system. The detecting system having the field of view narrower than that of the low-magnification detecting system may be a high-magnification detecting system or a detecting system with a field of view wider than that of the high-magnification detecting system.

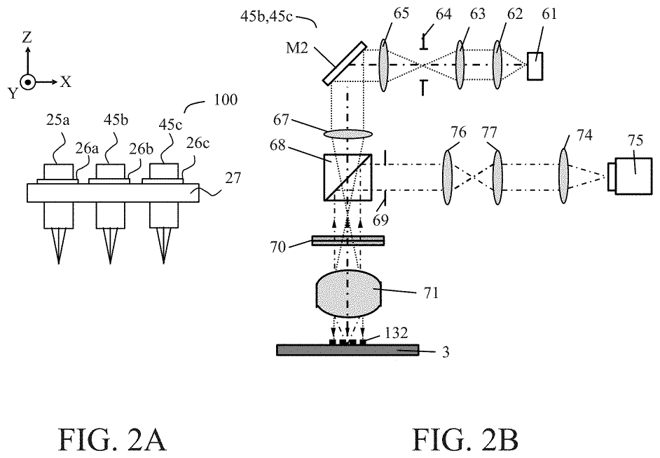

FIG. 2A is a configuration diagram of the mark detecting apparatus 100. The mark detecting apparatus 100 has a configuration in which the mark detecting systems 25b and 25c of the mark detecting apparatus 500 according to the comparative example are replaced with mark detecting systems 45b and 45c. FIG. 2B illustrates an example of the configuration of the mark detecting systems 45b and 45c. The configuration of the mark detecting system 25a is similar to that described with reference to FIG. 6B. In this embodiment, the mark detecting system 25a includes a low-magnification detecting system with a first magnification and a high-magnification detecting system with a second magnification higher than the first magnification. Each of the mark detecting systems 45b and 45c has only a high-magnification detecting system with a narrow field of view. In this embodiment, each of the mark detecting systems 45b and 45c has only the high-magnification detecting system having the second magnification. More specifically, each of the mark detecting systems 45b and 45c includes a configuration that eliminates the switching mirrors M3 and M4, the mirrors M5 and M6, and the low-magnification relay optical systems 78 and 79 from the configuration of the mark detecting system 25a from the high-magnification detecting system with a wide field of view and the low-magnification detecting system with a narrow field of view. Each of the mark detecting systems 45b and 45c may include a detecting system with a third magnification that is higher than the first magnification and lower than the second magnification. In a case where each of the mark detecting systems 45b and 45c includes the detecting system with the third magnification, the mark detecting system 25a may also include the detecting system with the third magnification.

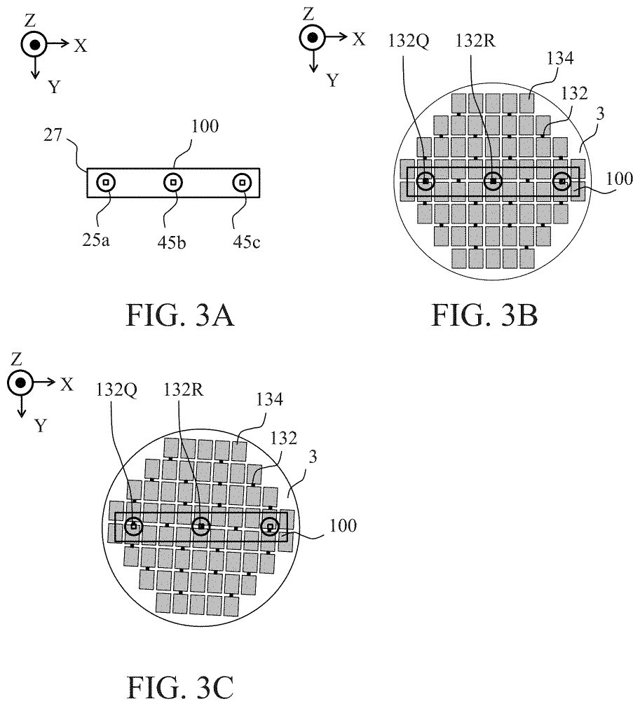

FIGS. 3A to 3C explain a method of performing rough detection to more accurately find the positions of the marks 132 on the wafer 3 using the mark detecting apparatus 100. FIG. 3A illustrates the mark detecting apparatus 100 viewed from the Z-axis direction. FIG. 3B illustrates a positional relationship between the mark detecting apparatus 100 and the marks 132 in the rough detection.

The mark detecting apparatus 100 performs rough detection of the marks 132 partially formed on the entire shot area using the mark detecting system 25a switched to the low-magnification detecting system, as illustrated in FIG. 3B, in consideration of productivity. At that time, by controlling the wafer stage WS, the marks 132 are aligned with the detection areas of the mark detecting systems 25a, 45b, and 45c, and the positions of the marks 132 are detected. At this time, the control unit 1100 controls the wafer stage WS so that the mark 132 to be detected by the high-magnification measurement system with a narrow field of view becomes closer to the center of the wafer 3 than the mark 132 to be detected by the low-magnification measurement system with a wide field of view. More specifically, the two marks 132 are simultaneously aligned with the detection area of the mark detecting system 25a and with the detection area of at least one of the mark detecting systems 45b and 45c, and the positions of these two marks 132 are detected. For example, as illustrated in FIG. 3B, two marks 132Q and 132R are simultaneously aligned with the mark detecting systems 25a and 45b, and the positions of the marks 132Q and 132R are detected. As illustrated in FIG. 3C, the mark 132R (second predetermined pattern), which is closer to the center of the wafer 3 than the mark 132Q (first predetermined pattern), is less susceptible to a rotation component among a driving error of the wafer 3 than the mark 132Q. That is, a shift amount of the mark 132R due to the rotation of the wafer 3 is smaller than that of the mark 132Q. Therefore, the detecting error of the mark 132R is small and it is less likely that the mark 132R shifts from the field of view of the high-magnification detecting system having a narrow field of view and the mark 132R becomes undetectable. In comparison with a case where a plurality of marks 132 are sequentially aligned with the detection area of one mark detecting system and the position of each mark 132 is detected, a moving amount of the wafer stage WS, that is, the driving time of the wafer stage WS and the detecting time of the mark detecting apparatus 100 can be shortened.

In a case where the position of the mark 132 could be detected by one of the primary eye and the secondary eye, it is highly likely to shorten the searching time by setting the detected mark 132 to a rotation axis and by searching in the rotating direction of the wafer 3.

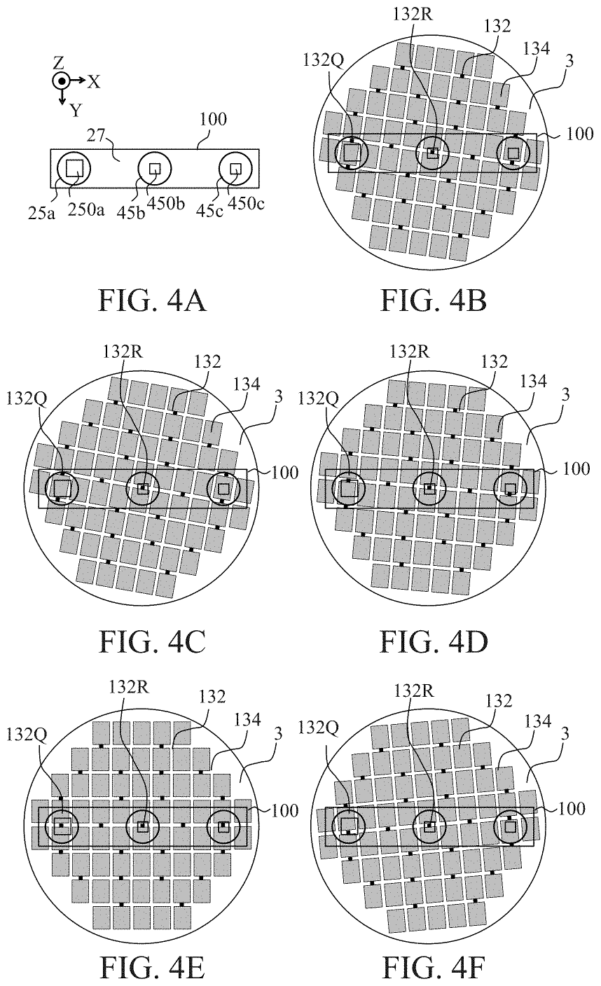

Referring now to FIGS. 4A to 4F, a description will be given of a specific example of the searching method. FIGS. 4A to 4F explain a searching method using the mark detecting apparatus 100. FIG. 4A illustrates the mark detecting apparatus 100 viewed from the Z-axis direction. FIG. 4A illustrates a field of view 250a of the low-magnification detecting system of the mark detecting system 25a and fields of view 450b and 450c of the mark detecting systems 45b and 45c. FIG. 4B illustrates a positional relationship between the mark detecting apparatus 100 and the marks 132 in a case where the mark 132R is detected only by the mark detecting system 45b after the rough detection.

As illustrated in FIGS. 4C to 4F, searching is performed in the rotating direction of the wafer 3 while the detected mark 132R is set to the rotation axis. Thereby, the mark 132Q can be efficiently searched that cannot be detected due to the influence of the rotation component in the driving error of the wafer 3.

The fields of view 250a, 450b, and 450c are merely illustrative, and the fields of view of the mark detecting systems according to this embodiment are not limited to this example. The number of mark detecting systems may be two, four, or more. The array of the primary eye and the secondary eye may be different from that in FIGS. 2A and 2B, and the primary eye and the secondary eye may not be aligned with the same straight line. For example, the primary eye may be configured to switch among three or more different fields of view, or the secondary eye may be configured to switch between two or more fields of view smaller than the maximum field of view of the primary eye. In addition, for example, the primary eye and the secondary eye may detect marks having different shapes or the same marks. Moreover, for example, the primary eye and the secondary eye may have different detection conditions such as illumination, illumination wavelengths, and light control.

In the searching method according to this embodiment, the mark 132 could be detected only by the secondary eye, but the searching method is not limited to this embodiment. For example, the mark 132 may be detected only by the primary eye. That is, one of the primary eye and the secondary eye may be detected and the other may not be detected. Alternatively, the mark 132 may be detected only by the mark detecting system 45c instead of the mark detecting system 45b.

As described above, this embodiment performs the rough detection of the marks 132 located at the periphery of the wafer 3 using the low-magnification detecting system of the detecting system (primary eye) that includes both the low-magnification detecting system with the wide field of view and the high-magnification detecting system with the narrow field of view. In addition, the mark 132 located at the center of the wafer 3 is detected by the detecting system (secondary eye) that includes only the high-magnification detecting system with the narrow field of view. Thereby, the configuration of the mark detecting apparatus 100 according to this embodiment can be made simple, and the space required for the configuration can be reduced. Therefore, the configuration according to this embodiment can realize the mark detecting apparatus 100 that can detect the positions of the plurality of marks 132 on the wafer 3 at high speed and with high accuracy with a simple configuration.

### Second Embodiment

A basic configuration of an exposure apparatus according to this embodiment is similar to that of the exposure apparatus 1 according to the first embodiment, but the exposure apparatus according to this embodiment is different in having a mark detecting apparatus 100 with a different configuration from that of the exposure apparatus 1 according to the first embodiment. In this embodiment, a configuration different from that of the first embodiment will be described, and a description of a similar configuration will be omitted.

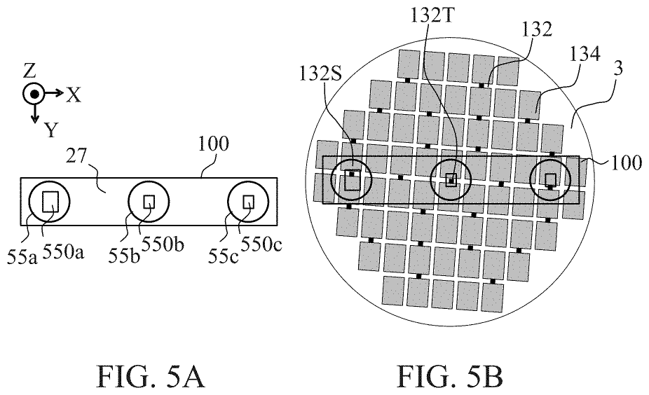

FIGS. 5A and 5B are configuration diagrams of the mark detecting apparatus 100 according to this embodiment. The mark detecting apparatus 100 includes a detecting system (primary eye) that includes both a low-magnification detecting system and a high-magnification detecting system, and a detecting system (secondary eye) that includes only the high-magnification detecting system. The primary eye is disposed so that a longitudinal direction of its field of view is orthogonal a direction connecting the center of the field of view of the primary eye and the center of the field of view of the secondary eye. During pre-alignment, the mark 132 located at the periphery of the wafer 3 is measured by the low-magnification detecting system of the primary eye, and the mark 132 located at the center of the wafer 3 is measured by the secondary eye. Thereby, it is less likely even with the driving error of the rotation component of the wafer 3 that the mark 132R shifts from the field of view of the primary eye and the mark 132R becomes undetectable.

FIG. 5A illustrates the mark detecting apparatus 100 viewed from the Z-axis direction. A mark detecting system 55a has a configuration similar to that described with reference to FIG. 6B. Each of the mark detecting systems 55b and 55c has a configuration similar to that described with reference to FIG. 2B. FIG. 5A illustrates a field of view 550a of the low-magnification detecting system of the mark detecting system 55a and fields of view 550b and 550c of the mark detecting systems 55b and 55c. FIG. 5B illustrates a positional relationship between the mark detecting apparatus 100 and marks 132T and 132S on the wafer 3 in the rough detection. As described above, the primary eye is disposed so that a longitudinal direction of its field of view is orthogonal to a direction connecting the center of the field of view of the primary eye and the center of the field of view of the secondary eye. Therefore, even with the driving error of the rotation component of the wafer 3, the mark 132S is likely to enter the field of view of the primary eye and the searching frequency can be reduced.

As described above, the configuration according to this embodiment can realize the mark detecting apparatus 100 that can detect the positions of the plurality of marks 132 on the wafer 3 at high speed and with high accuracy with a simple configuration.

### Embodiment of Substrate Processing Apparatus

The first and second embodiments have discussed an exposure apparatus that exposes a substrate to form a pattern onto the substrate as an example of the substrate processing apparatus, but the disclosure is not limited to these embodiments. For example, the disclosure is applicable to a substrate processing apparatus such as an imprint apparatus that forms a pattern of an imprint material onto a substrate using a mold, or a drawing apparatus that forms a pattern onto a substrate by irradiating the substrate with a charged particle beam. The disclosure is also applicable to a substrate processing apparatus such as a coating apparatus for applying a photosensitive medium onto a surface of the substrate and a developing apparatus for developing a photosensitive medium on which a pattern has been transferred. The disclosure is also applicable to a substrate processing apparatus such as a film forming apparatus (such as a chemical vapor deposition (CVD) apparatus), a processing apparatus (such as a laser processing apparatuses), an inspection apparatus (such as an overlay inspection apparatus), and a measuring apparatus (such as a mark measuring apparatus).

### Embodiment of Article Manufacturing Method

An article manufacturing method according to the embodiment of the disclosure is suitable for manufacturing an article, such as a micro device (e.g., semiconductor device), an element having a fine structure, and a flat panel display. The article manufacturing method according to this embodiment includes the steps of processing a substrate using the substrate processing apparatus described above and manufacturing an article from the substrate processed by the above step. This manufacturing method can include well-known steps (such as exposure, oxidation, film formation, vapor deposition, doping, planarization, etching, resist stripping, dicing, bonding, and packaging). The article manufacturing method according to this embodiment is more advantageous in at least one of article performance, quality, productivity, and production cost than the conventional methods.

Each of the above embodiments can provide a detecting apparatus that can detect positions of a plurality of marks on a substrate with high speed and high accuracy with a simple configuration.

While the disclosure has been described with reference to exemplary embodiments, it is to be understood that the disclosure is not limited to the disclosed exemplary embodiments. The scope of the following claims is to be accorded the broadest interpretation so as to encompass all such modifications and equivalent structures and functions.

This application claims the benefit of Japanese Patent Application No. 2021-197756, filed on Dec. 6, 2021, which is hereby incorporated by reference herein in its entirety.

What is claimed is:

1. A detecting apparatus configured to detect a position of a predetermined pattern on a substrate, the detecting apparatus comprising:
a first detecting system configured to detect a position of a first predetermined pattern in a first field of view; and
a second detecting system configured to detect a position of a second predetermined pattern with a smaller shift amount than that of the first predetermined pattern in a second field of view narrower than the first field of view.

2. The detecting apparatus according to claim 1, wherein a field of view of the first detecting system can be switched to a third field of view narrower than the first field of view.

3. The detecting apparatus according to claim 2, wherein after detecting the position of the first predetermined pattern in the first field of view, the first detecting system detects the position of the first predetermined pattern in the third field of view.

4. The detecting apparatus according to claim 2, wherein after the first detecting system detects the position of the first predetermined pattern in the first field of view and the second detecting system detects the position of the second predetermined pattern, the first detecting system detects the position of the first predetermined pattern in the third field of view and the second detecting system detects the position of the second predetermined pattern.

5. The detecting apparatus according to claim 1, wherein the first detecting system includes a detecting system of a first magnification and a detecting system of a second magnification higher than the first magnification, and
wherein the second detecting system includes a detecting system of the second magnification.

6. The detecting apparatus according to claim 1, wherein the first detecting system includes a detecting system of a first magnification and a detecting system of a second magnification higher than the first magnification, and
wherein the second detecting system includes a detecting system of the first magnification and a detecting system of a third magnification higher than the first magnification and lower than the second magnification.

7. The detecting apparatus according to claim 1, wherein the first detecting system includes a detecting system of a first magnification, a detecting system with a second magnification higher than the first magnification, and a detecting system of a third magnification higher than the first magnification and lower than the second magnification, and
wherein the second detecting system includes a detecting system of the first magnification and a detecting system of the third magnification.

8. The detecting apparatus according to claim 1, wherein the first detecting system includes a detecting system of a first magnification, and
wherein the second detecting system includes a detecting system of a second magnification higher than the first magnification.

9. The detecting apparatus according to claim 1, wherein detection of the position of the first predetermined pattern by the first detecting system is performed simultaneously with detection of the position of the second predetermined pattern by the second detecting system.

10. The detecting apparatus according to claim 1, wherein the first detecting system is disposed so that a longitudinal direction of the first field of view is orthogonal to a direction connecting a center of the first field of view and a center of the second field of view to each other.

11. A substrate processing apparatus configured to process a substrate, the substrate processing apparatus comprising a detecting apparatus configured to detect a position of a predetermined pattern on the substrate,
wherein the detecting apparatus includes:
a first detecting system configured to detect a position of a first predetermined pattern in a first field of view; and
a second detecting system configured to detect a position of a second predetermined pattern with a smaller shift amount than that of the first predetermined pattern in a second field of view narrower than the first field of view.

12. The substrate processing apparatus according to claim 11, wherein a moving amount of the substrate in a case where the first detecting system detects the position of the first predetermined pattern and the second detecting system detects the position of the second predetermined pattern, is shorter than a moving amount of the substrate in a case where one of the first detecting system and the second detecting system is used to detect the position of the first predetermined pattern and the position of the second predetermined pattern.

13. The substrate processing apparatus according to claim 11, wherein in a case where one of the first predetermined pattern and the second predetermined pattern is detected and the other is not detected, the other is searched by rotating the substrate using the one as a rotation axis.

14. An article manufacturing method comprising the steps of:
processing a substrate using a substrate processing apparatus configured to process the substrate; and
manufacturing an article from a processed substrate,
wherein the substrate processing apparatus includes a detecting apparatus configured to detect a position of a predetermined pattern on the substrate, and
wherein the detecting apparatus includes:
a first detecting system configured to detect a position of a first predetermined pattern in a first field of view; and
a second detecting system configured to detect a position of a second predetermined pattern with a smaller shift amount than that of the first predetermined pattern in a second field of view narrower than the first field of view.
